(19) United States
(12) Patent Application Publication
(10) Pub. No.: US 2002/0106588 A1
(43) Pub. Date: Aug. 8, 2002

(54) Photolithography process for forming an opening

(76) Inventors: Chien-Wen Lai, Taipei Hsien (TW); Chien-Ming Wang, Hsinchu Hsien (TW); Andersen Chang, Miaoli Hsien (TW); Hui-Ling Huang, Hsinchu (TW)

Correspondence Address: CHARLES C.H. WU & ASSOCIATES, Suite 710, 7700 IRVINE CENTER DRIVE, Irvine, CA, 92618-3043, US

(21) Appl. No.: 09/781,806

(22) Filed: Feb. 12, 2001

(30) Foreign Application Priority Data
Feb. 6, 2001 (TW) 90102501

(51) Int. Cl. G03F 7/20

(52) U.S. Cl. 430/322; 430/394; 430/396

(57) ABSTRACT

The invention provides a lithography process for forming openings. The method comprises forming a negative photoresist layer. A first mask is used to transfer a first strip pattern to the negative photoresist layer, so that a plurality of first strips, parallel to each other, are formed. A second mask is used to transfer a second strip pattern to the negative photoresist layer, forming a plurality of second strips, parallel to each other. Because the second strip pattern is perpendicular to the first strip pattern, the combined exposure of these two patterns forms a plurality of opening patterns. A trim mask is used to transfer a pattern to the negative photoresist layer for shielding the opening patterns in specific regions and exposing the opening patterns outside the specific regions to light. The negative photoresist layer is then developed.

### CROSS-REFERENCE TO RELATED APPLICATION

This application claims the priority benefit of Taiwan application serial no. 90102501, filed Feb. 6, 2001.

### BACKGROUND OF THE INVENTION

1. Field of Invention

The present invention relates to a method of fabricating integrated circuits. More particularly, the present invention relates to a lithography process for forming an opening.

2. Description of Related Art

As integration of the semiconductor device increases, dimensions of the device decrease to even smaller than the wavelength of deep ultra-violet (UV) light. Therefore, specific methods are applied to improve the resolution and the depth of focus for the manufacture processes. For example, in order to obtain an opening pattern having a size of 120 nm with the deep UV (DUV) light source of 248 nm, many factors, including the exposure system, the mask type and the material of the photoresist, need to be carefully considered.

In the lithography process, the resolution R can be represented as the following equation:

R=k1λ/NA

wherein λ is the wavelength of the exposure light source; NA is the numerical aperture of the exposure system; and k1 is a constant relating to the mask type and the material of the photoresist. There is a conventional lithography method applying the alternating phase shifter mask (PSM) together with the negative photoresist in order to decrease the k1 constant and thus to increase the resolution.

However, the conventional lithography method fails to provide enough contrast, depth of focus and mask error factor (MEF) for forming a via/contact opening in a 0.13 μm process using the DUV exposure light source of 248 nm. Furthermore, if the openings are arranged irregularly, the conventional method needs to perform optical proximity correction (OPC) to precisely control the critical dimension (CD) for each opening. Because the OPC masks are difficult to obtain, the conventional method is thus time-consuming and cost-ineffective.

### SUMMARY OF THE INVENTION

The invention provides a lithography process for forming openings. The method comprises forming a negative photoresist layer. A first mask is used to transfer a first strip pattern to the negative photoresist layer, so that a plurality of first strips, parallel to each other, are formed. A second mask is used to transfer a second strip pattern to the negative photoresist layer, forming a plurality of second strips, parallel to each other. Because the second strips are perpendicular to the first strips, the combined exposure of these two patterns forms a plurality of opening patterns. A trim mask is used to transfer a pattern to the negative photoresist layer for shielding the opening patterns in specific regions and exposing the opening patterns outside the specific regions to light. The negative photoresist layer is then developed.

Moreover, the size of the opening pattern is between one half of the exposure light wavelength to the exposure light wavelength. The first mask is, for example, an alternating strong PSM mask having a transparency of 100%.

According to the aerial image superposition theory, this invention takes advantage of the results of combined optical effects of the first strip pattern and the second strip pattern, resulting in regularly arranged opening patterns. Because the strip patterns have better contrast than the opening patterns, the opening patterns, resulting from the combined exposure forming two perpendicular strip patterns, are of better quality. Furthermore, by combining the exposure of two strip patterns, this invention forms regularly arranged opening patterns, all over the photoresist layer. Afterwards, using the trim mask to shield specific regions, only the opening patterns in the specific regions remain to form openings. In this way, the opening patterns are formed regularly in specific regions with similar optical conditions. Therefore, no optical proximity correction is required for each opening pattern in the masks, thus reducing the cost and the time.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 to 3 are graphs illustrating steps of the lithography process for forming openings according to one preferred embodiment of this invention; and

FIGS. 1A to 3A are graphs of three masks used in three steps of the lithography process according to one preferred embodiment of this invention.

### DESCRIPTION OF THE PREFERRED EMBODIMENTS

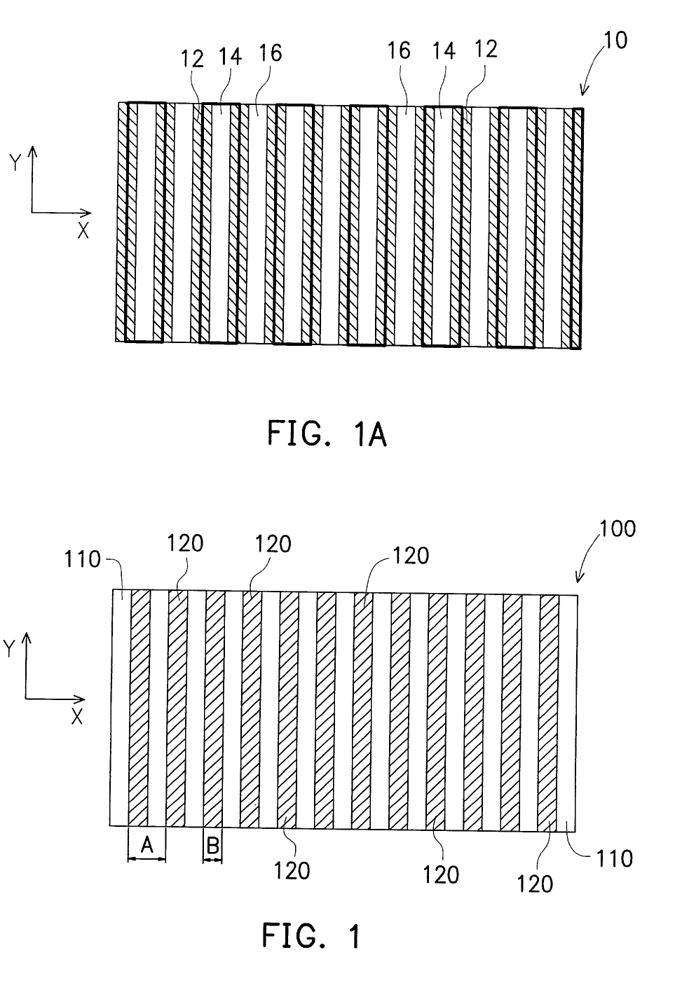

FIGS. 1A to 3A are graphs of three masks used in three steps of the lithography process according to one preferred embodiment of this invention.

Referring to FIG. 1A, a graph of a mask is used in a first step of the lithography process for forming an opening. An alternating strong PSM mask 10 is provided including alternating and parallel opaque strip regions 12 with a same pitch/size. The opaque strip regions 12 alternate with alternating strong phase shifter regions 14 (within regions marked in bold) and transparent regions 16. The alternating strong phase shifter regions 14 have a transparency of 100%. The phase of the alternating strong phase shifter regions 14 is different to that of the transparent regions 16 in 180 degrees. As a result of the phase shifting, the incoming light intensity over the regions between the alternating strong phase shifter regions 14 and the transparent regions 16 is reduced, thus improving resolution.

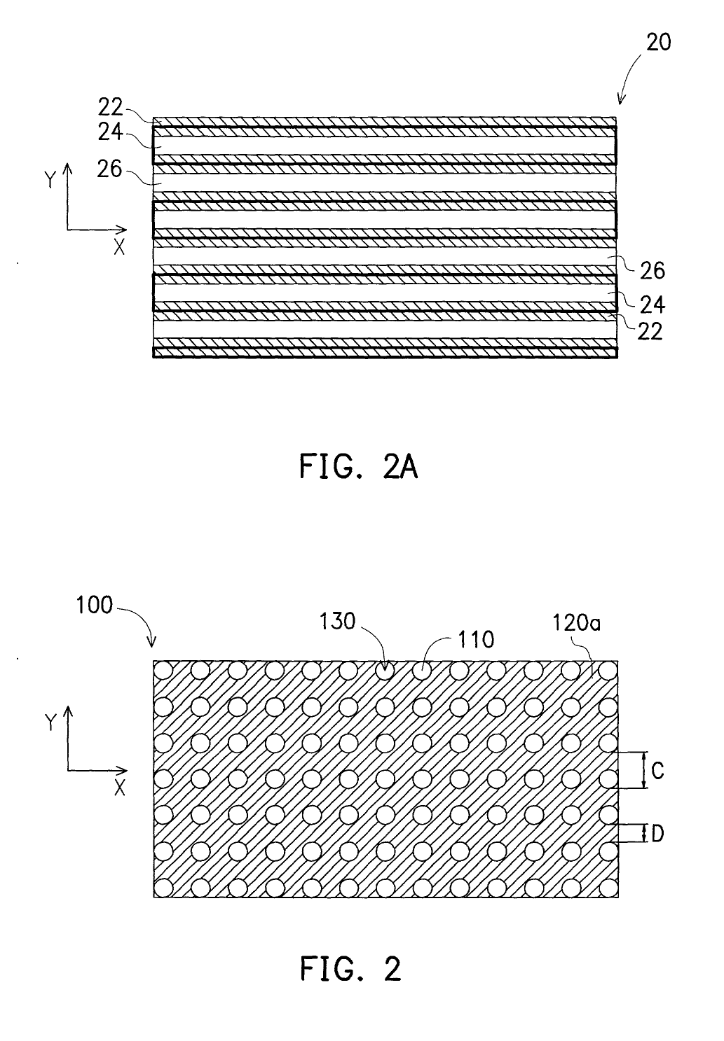

Referring to FIG. 2A, a graph of a mask is used in a second step of the lithography process for forming an opening. An alternating strong PSM mask 20 is provided including alternating and parallel opaque strip regions 22 with a same pitch/size. The opaque strip regions 22 are arranged perpendicularly to the opaque strip regions 12 in FIG. 1A. The opaque strip regions 22 alternate with alternating strong phase shifter regions 24 (within regions marked in bold) and transparent regions 26. The alternating strong phase shifter regions 24 have a transparency of 100%. The phase of the alternating strong phase shifter regions 24 is different to that of the transparent regions 26 in 180 degrees. As a result of the phase shifting, the incoming light intensity over the regions between the alternating strong phase shifter regions 24 and the transparent regions 26 is reduced, thus improving resolution.

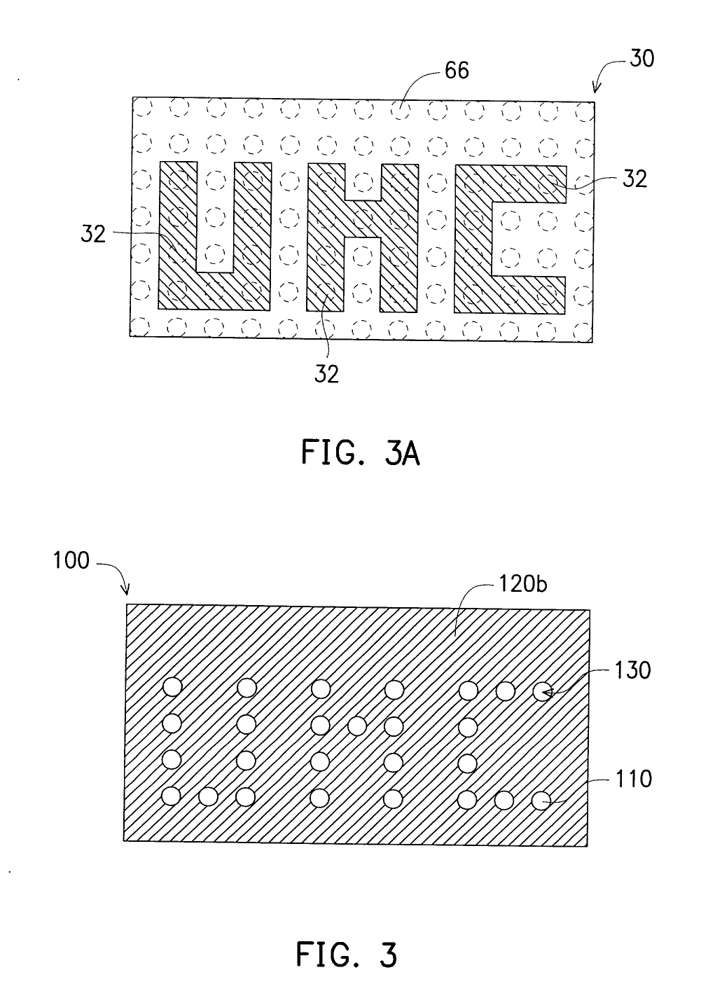

Referring to FIG. 3A, a graph of a mask used in a third step of the lithography process for forming an opening. A trim mask 30 is provided with opaque regions 32 in the shape of “UHC”. The opaque regions 32, covered by chromium, are corresponding to regions that are designated to form openings.

FIG. 1 to FIG. 3 are graphs illustrating the steps of the lithography process for forming openings according to one preferred embodiment of this invention.

Referring to FIG. 1, a substrate 100 is provided. A negative photoresist layer 110 is formed on the substrate 100. The alternating strong PSM mask 10 is used for exposure to transfer a first strip pattern 120 to the negative photoresist layer 110, so that first strips are formed in the negative photoresist layer. The first strip pattern is in the direction of the Y axis. The first strip pattern 120 has a pitch “A” and a size “B” and the pitch “A” is double that of the size “B”. For example, using the exposure light source of 248 nm, the pitch “A” is about 240 nm and the size “B” is 120±10% nm (around one half of 248 nm).

Referring to FIG. 2, the alternating strong PSM mask 20 is used for exposure to transfer a second strip pattern 220 to the negative photoresist layer 110, so that second strips (not shown in its original pattern) are transferred to the negative photoresist layer. The second strip pattern 220 is in the direction of the X axis. The second strip pattern 220 has a pitch “C” and a size “D” and the pitch “C” is double that of the size “D”. For example, using the exposure light source of 248 nm, the pitch “C” is about 240 nm and the size “D” is 120±10% nm (around one half of 248 nm). An exposure pattern 120a is formed as a result of combined optical effects of the Y-axis strip pattern 120 and the X-axis strip pattern 220. The exposure pattern 120a contains regularly arranged opening patterns 130, resulting from the combined exposure forming two perpendicular patterns. The double exposure causes rounding in the crossovers of different exposure, thus forming the opening patterns.

Referring to FIG. 3 together with FIG. 3A, regions 66 (marked in dashed line) in the mask 30 correspond to the opening patterns 130. The trim mask 30 is used for exposure to transfer a pattern to the negative photoresist layer 110, so that the opening patterns 130, except for the opening patterns 130 shielded by the “UMC”-shape opaque region 32, are exposed to light, thus forming the exposure pattern 120b after the third exposure step.

After developing, the opening patterns 130 shielded by the “UMC”-shape opaque region 32 are washed away by the developer to form round openings (not shown).

As cited in the above, this invention takes advantage of the results of combined optical effects of the Y-axis strip pattern and the X-axis strip pattern, resulting in regularly arranged opening patterns 130. Because the strip patterns have better contrast than the opening patterns, the opening patterns 130, resulting from the combined exposure forming two perpendicular strip patterns, are of better quality. Furthermore, this invention forms the regularly arranged opening patterns 130, by combining exposure of two strip patterns, all over the photoresist layer. Afterwards, using the trim mask 30 to shield specific regions (corresponding to the “UMC”-shape), only the opening patterns 130 in the specific regions remain to form openings. In this way, the opening patterns 130 are formed regularly in specific regions with similar optical conditions. Therefore, no optical proximity correction is required for each opening pattern in the masks 10, 20 and 30, thus reducing the cost and the time.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A lithography process for forming openings, comprising:
forming a negative photoresist layer on a substrate;
using a first mask to transfer a first strip pattern to the negative photoresist layer for forming a plurality of first strips that are parallel to each other;
using a second mask to transfer a second strip pattern to the negative photoresist layer for forming a plurality of second strips that are parallel to each other, wherein the second strip pattern is perpendicular to the first strip pattern and combination of the first and the second strip patterns results in forming a plurality of opening patterns;
using a trim mask to transfer a pattern to the negative photoresist layer for shielding the opening patterns in specific regions and exposing the opening patterns outside the specific regions to light; and
developing the negative photoresist layer to form a plurality of openings.

2. The process as claimed in claim 1, wherein the first mask comprises an alternating strong phase shifter mask.

3. The process as claimed in claim 1, wherein the second mask comprises an alternating strong phase shifter mask.

4. The process as claimed in claim 1, wherein the trim mask has opaque regions for shielding the specific regions.

5. The process as claimed in claim 4, wherein a material of the opaque regions comprises chromium.

6. The process as claimed in claim 1, wherein the openings comprise contact/via openings.

7. The process as claimed in claim 1, wherein a light source having a wavelength is used for transferring the patterns and the sizes of the opening patterns are between one half of the wavelength to the wavelength.

8. The process as claimed in claim 1, wherein a light source having a wavelength of 248 nm is used.

9. The process as claimed in claim 1, wherein a size of the opening is 120±10% nm.

10. The process as claimed in claim 1, wherein a pitch of the first strip pattern is 240 nm.

11. The process as claimed in claim 1, wherein a pitch of the second strip pattern is 240 nm.

12. A lithography process for forming openings, comprising:
forming a negative photoresist layer on a substrate;
using a first mask to transfer a first strip pattern to the negative photoresist layer for forming a plurality of first strips that are parallel to each other;
using a second mask to transfer a second strip pattern to the negative photoresist layer for forming a plurality of second strips that are parallel to each other, wherein the second strip pattern is perpendicular to the first strip pattern and combination of the first and the second strip patterns results in forming a plurality of opening patterns;
using a trim mask to transfer a pattern to the negative photoresist layer for shielding the opening patterns in specific regions and exposing the opening patterns outside the specific regions to light, wherein the trim mask has opaque regions for shielding the specific regions; and
developing the negative photoresist layer to form a plurality of openings.

13. The process as claimed in claim 12, wherein a material of the opaque regions comprises chromium.

14. The process as claimed in claim 12, wherein the openings comprise contact/via openings.

15. The process as claimed in claim 12, wherein a light source having a wavelength is used for transferring the patterns and the sizes of the opening patterns are between one half of the wavelength to the wavelength.

16. The process as claimed in claim 12, wherein a light source having a wavelength of 248 nm is used.

17. The process as claimed in claim 12, wherein a size of the opening pattern is 120±10% nm.

18. The process as claimed in claim 12, wherein the first strip pattern and the second strip pattern have a same pitch.

19. The process as claimed in claim 12, wherein the pitch of the first strip pattern is 240 nm.

20. The process as claimed in claim 12, wherein the pitch of the second strip pattern is 240 nm.
